(19) United States
(12) Patent Application Publication
(10) Pub. No.: US 2026/0353885 A1
(43) Pub. Date: Nov. 5, 2026

(54) LIGHT EMITTING DEVICE

(71) Applicant: SONY SEMICONDUCTOR SOLUTIONS CORPORATION, Kanagawa (JP)

(72) Inventors: Toshiaki HASEGAWA, Kanagawa (JP); Toshihiro MIURA, Kanagawa (JP); Hiroyuki KASHIHARA, Kanagawa (JP)

(73) Assignee: SONY SEMICONDUCTOR SOLUTIONS CORPORATION, Kanagawa (JP)

(21) Appl. No.: 19/101,835

(22) PCT Filed: Jun. 28, 2023
(86) PCT No.: PCT/JP2023/023902

§ 371 Date: Feb. 6, 2025

(30) Foreign Application Priority Data
Aug. 19, 2022 (JP) 2022-131103

(51) Int. Cl. H10H 29/45; H10H 29/32; H10H 29/80; H10H 29/851

(52) U.S. Cl. CPC H10H 29/45; H10H 29/32; H10H 29/8321; H10H 29/8325; H10H 29/8515

(57) ABSTRACT

A light emitting device includes: a first compound semiconductor layer having a first conductivity type; an active layer stacked on the first compound semiconductor layer; a second compound semiconductor layer on the active layer stacked on an opposite side of the first compound semiconductor layer, the second compound semiconductor layer having a second conductivity type opposite to the first conductivity type; a first reflective layer disposed away from a surface of the second compound semiconductor layer on an opposite side of the active layer, the first reflective layer reflecting light emitted from the active layer; and a first electrode disposed between the second compound semiconductor layer and the first reflective layer, the first electrode electrically connecting a part of the second compound semiconductor layer and of the first reflective layer.

### TECHNICAL FIELD

The present disclosure relates to a support for supporting a display unit, and a display device including a display unit and a support.

### BACKGROUND ART

PTL 1 discloses a micro light emitting element. This micro light emitting element includes compound semiconductors stacked on a driving circuit board. The compound semiconductors are formed by sequentially stacking a p-type layer, a light emitting layer, and an n-type layer on the drive circuit board in this order. The p-type layer is electrically coupled to the p electrode, and the n-type layer is electrically coupled to the n electrode.

The micro light emitting element configured in this manner lets light from the light emitting layer exit through the n-type layer, thus configurating an image display element.

### CITATION LIST

### Patent Literature

PTL 1: Japanese Unexamined Patent Application Publication No. 2019-204823

### SUMMARY OF THE INVENTION

The above micro light emitting element includes a transparent electrode formed on the entire surface of the p-type layer of the compound semiconductors facing the drive circuit board, and the p-type layer is electrically coupled to the p electrode via this transparent electrode. The p electrode is formed over most of the entire surface of the p-type layer.

However, for the above-described micro light emitting element, no consideration is given to the leakage of light emitted from the light emitting layer to the drive circuit board. Therefore, with further miniaturization of light emitting devices, it is desirable to improve the light extraction efficiency and achieve an image display device with higher image quality.

A light emitting device according to the first embodiment of the present disclosure includes: a first compound semiconductor layer having a first conductivity type; an active layer stacked on the first compound semiconductor layer; a second compound semiconductor layer on the active layer stacked on an opposite side of the first compound semiconductor layer, the second compound semiconductor layer having a second conductivity type opposite to the first conductivity type; a first reflective layer disposed away from a surface of the second compound semiconductor layer on an opposite side of the active layer, the first reflective layer reflecting light emitted from the active layer; and a first electrode disposed between the second compound semiconductor layer and the first reflective layer, the first electrode electrically connecting a part of the second compound semiconductor layer and of the first reflective layer.

A light emitting device according to the second embodiment of the present disclosure further includes, in the light emitting device according to the first embodiment, an insulator between the second compound semiconductor layer and the first reflective layer, the insulator being light transmissive and insulating.

In a light emitting device according to the third embodiment of the present disclosure, at least a portion of the first compound semiconductor layer, the active layer, and the second compound semiconductor layer have a mesa shape in the light emitting device according to the first embodiment or the second embodiment, and the light emitting device further includes a second reflective layer disposed along a side face of the mesa shape, the second reflective layer reflecting light emitted from the active layer and light reflected from the first reflective layer toward the first compound semiconductor layer.

A light emitting device according to the fourth embodiment of the present disclosure further includes: in the light emitting device according to any one of the first embodiment through the third embodiment, a second electrode on the first reflective layer on an opposite side of the second compound semiconductor layer, the second electrode including a lamination of a barrier metal layer, an Al alloy layer, and a barrier metal layer that are sequentially stacked.

### BRIEF DESCRIPTION OF DRAWING

FIG. 1 is a schematic cross-sectional view of a light emitting device according to a first embodiment of the present disclosure.

FIG. 2 is an enlarged plan view of a major part of the light emitting device illustrated in FIG. 1.

FIG. 3 is an enlarged cross-sectional view of a light emitting element that constitutes the light emitting device illustrated in FIG. 1 and FIG. 2.

FIG. 4 is a bottom view of a major part of the light emitting element illustrated in FIG. 3, illustrating the configuration of a first reflective layer and a first electrode of the light emitting element.

FIG. 5 explains the method for manufacturing the light emitting device according to the first embodiment, which is a cross-sectional view of a first process corresponding to FIG. 3.

FIG. 6 is a cross-sectional view of a second process.

FIG. 7 is a cross-sectional view of a third process.

FIG. 8 is a cross-sectional view of a fourth process.

FIG. 9 is a cross-sectional view of a fifth process.

FIG. 10 is a cross-sectional view of a sixth process.

FIG. 11 is a cross-sectional view of a seventh process.

FIG. 12 is a cross-sectional view of an eighth process.

FIG. 13 is a bottom view of a major part of a light emitting element that constitutes a light emitting device according to a second embodiment of the present disclosure, illustrating the configuration of a first reflective layer and a first electrode of the light emitting element.

FIG. 14 is a bottom view of a major part of a light emitting element that constitutes a light emitting device according to a first modification example of the second embodiment, illustrating the configuration of a first reflective layer and a first electrode of the light emitting element.

FIG. 15 is a bottom view of a major part of a light emitting element that constitutes a light emitting device according to a second modification example of the second embodiment, illustrating the configuration of a first reflective layer and a first electrode of the light emitting element.

FIG. 16 is an enlarged cross-sectional view of a light emitting element that constitutes a light emitting device according to a third embodiment of the present disclosure, corresponding to FIG. 3.

FIG. 17 is a bottom view of a major part of the light emitting element illustrated in FIG. 16, illustrating the configuration of a first reflective layer and a first electrode of the light emitting element, and corresponding to FIG. 4.

FIG. 18 is an enlarged cross-sectional view of a light emitting element that constitutes a light emitting device according to a fourth embodiment of the present disclosure, corresponding to FIG. 3.

FIG. 19 is a bottom view of a major part of the light emitting element illustrated in FIG. 18, illustrating the configuration of a first reflective layer and a first electrode of the light emitting element, and corresponding to FIG. 4.

FIG. 20 is an enlarged cross-sectional view of a light emitting element that constitutes a light emitting device according to a fifth embodiment of the present disclosure, corresponding to FIG. 3.

FIG. 21 is a block diagram depicting an example of schematic configuration of a vehicle control system.

FIG. 22 is a diagram of assistance in explaining an example of installation positions of an outside-vehicle information detecting section and an imaging section.

### MODES FOR CARRYING OUT THE INVENTION

The following describes embodiments of the present disclosure in details with reference to the drawings. Note that the explanation will be given in the following order.
1. First Embodiment

The first embodiment describes a first example of applying the present technology to a light emitting device and a manufacturing method thereof.
2. Second Embodiment

The second embodiment describes a second example of changing the configuration of the light emitting elements in the light emitting device according to the first embodiment.
3. Third Embodiment

The third embodiment describes a third example of changing the configuration of the light emitting elements in the light emitting device according to the first embodiment or the second embodiment.
4. Fourth Embodiment

The fourth embodiment describes a fourth example of changing the configuration of the light emitting elements in the light emitting device according to the first embodiment through the third embodiment.
5. Fifth Embodiment

The fifth embodiment describes a fifth example of changing the configuration of the light emitting elements in the light emitting device according to the first embodiment through the fourth embodiment.
6. Examples of Applications to Moving Objects

This application example describes an example of applying the present technology to a vehicle control system, which is an example of a mobile body control system.
7. Other Embodiments

### 1. First Embodiment

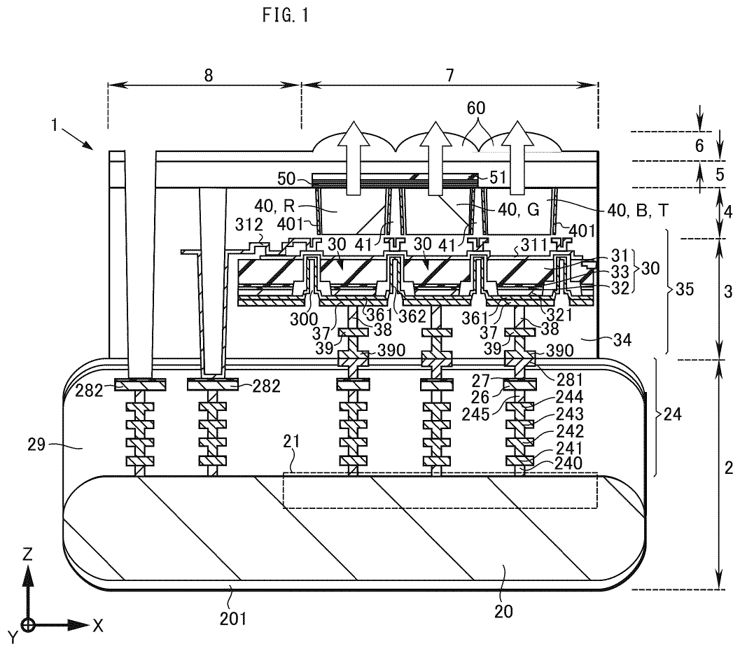

Referring to FIGS. 1 to 12, the following describes a light emitting device 1 and a manufacturing method thereof according to the first embodiment of the present disclosure.

Here, the direction of arrow X in the drawings illustrated as appropriate indicates one planar direction when the light-emitting device 1 is placed on a plane for the sake of convenience. The direction of arrow Y indicates another plane direction orthogonal to the arrow X direction. The direction of arrow Z indicates upward direction orthogonal to the arrow X direction and arrow Y direction. The arrow X direction, arrow Y direction, and arrow Z direction exactly coincide with the X-axis direction, Y-axis direction, and Z-axis direction, respectively, of the three-dimensional coordinate system.

Note that these directions are illustrated to help understand the present technology, and do not limit the directions of the present technology.

### Configuration of Light Emitting Device 1

### (1) Overall Configuration of Light Emitting Device 1

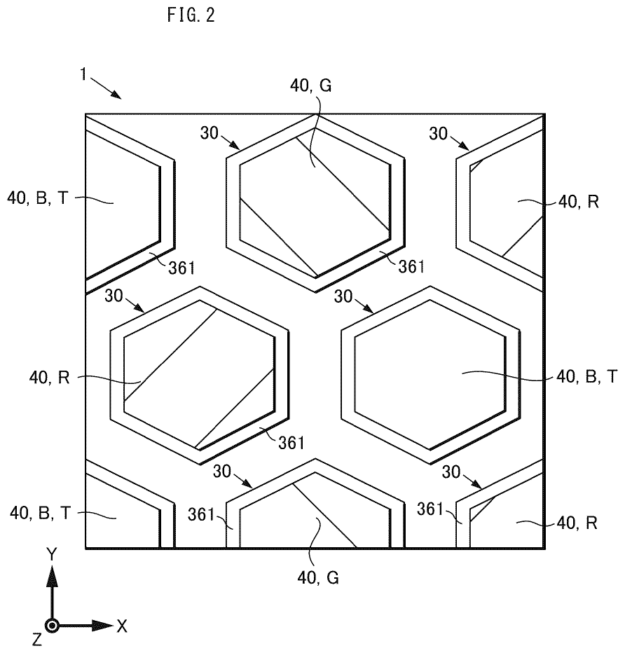

FIG. 1 illustrates an example of the schematic cross-sectional configuration of a light emitting device 1 according to the first embodiment. FIG. 2 illustrates an example of the planar configuration of light emitting elements 30 and color conversion layers 40 of the light emitting device 1.

As illustrated in FIG. 1, the light emitting device 1 according to the first embodiment includes a substrate region 2, a light emitter region 3, a color conversion region 4, a filter region 5, and an optical system region 6 in the longitudinal cross-sectional direction that is the arrow Z direction. The light emitting device 1 also includes an element array region 7 and a peripheral region 8 in planar directions that are arrow X and arrow Y directions.

The light emitting device 1 includes, as its major components, a substrate 20 in the substrate region 2, and a light emitter 35 placed in the light emitter region 3 and including a plurality of light emitting elements 30 arranged in the element array region 7.

### (2) Configuration of Substrate Region 2

The substrate region 2 includes the substrate 20 and a driving circuit 21 mounted on the main surface of the substrate 20. The main surface of the substrate 20 refers to one main surface of the substrate 20, on which semiconductor elements (not illustrated), such as drive transistors, are manufactured and on which the drive circuit 21 is further formed.

For instance, the substrate 20 may include a single crystal silicon (Si) substrate. The substrate 20 has a rear face opposite to the main surface, and side faces, and an insulator 201 is formed on these rear face and side faces. Practically, the insulator 201 may include a silicon nitride (SiN) film or a silicon oxide (SiO) film, for example.

### (2-1) Configuration of Drive Circuit 21

The drive circuit 21 includes semiconductor elements, not illustrated, formed on the main surface of the substrate 20. The driving transistors as semiconductor elements each include a complementary insulated gate field effect transistor (IGFET), for example. Insulated gate field effect transistors each include at least both a field effect transistor having a metal/insulator/semiconductor configuration (MISFET) and a field effect transistor having a metal/oxide film/semiconductor structure (MOSFET).

### (2-2) Configuration of Wiring Layer 24

The driving circuit 21 is electrically coupled to the first terminal 281 through the wiring layer 24. The wiring layer 24 in this embodiment includes a plug wiring 240, a first layer wiring 241, a second layer wiring 242, a third layer wiring 243, a fourth layer wiring 244, and a plug wiring 245.

The plug wiring 240 is formed on the main electrode of an insulated gate field effect transistor (not illustrated), for example, and is electrically coupled to this main electrode. For instance, the plug wiring 240 includes tungsten (W).

The first layer wiring 241 is formed on the plug wiring 240 to be electrically coupled to the plug wiring 240. The second layer wiring 242 is formed on the first layer wiring 241 to be electrically coupled to the first layer wiring 241. The third layer wiring 243 is formed on the second layer wiring 242 to be electrically coupled to the second layer wiring 242. The fourth layer wiring 244 is formed on the third layer wiring 243 to be electrically coupled to the third layer wiring 243. The first layer wiring 241 to the fourth layer wiring 244 each mainly include aluminum (Al), for example.

The plug wiring 245 is formed on the fourth layer wiring 244 to be electrically coupled to the fourth layer wiring 244. The plug wiring 245 includes a similar material to the plug wiring 240, for example.

The wiring layer 24 also includes an insulator 29. The insulator 29 is formed around the plug wiring 240 and plug wiring 245. The insulator 29 also is formed between the first layer wiring 241 and the second layer wiring 242, between the second layer wiring 242 and the third layer wiring 243, and between the third layer wiring 243 and the fourth layer wiring 244, for example. The insulator 29 includes a SiO film or a SiN film, for example.

### (2-3) Configuration of Light Shielding Film 26 and Light Absorbing Film 27

In the wiring layer 24, the first terminal 281 is electrically coupled to the plug wiring 245 through the light absorbing film 27 and the light shielding film 26 in this order.

The light shielding film 26 is placed closer to the drive circuit 21 than the light absorbing film 27. Here, the light shielding film 26 covers the drive transistor of the drive circuit 21, for example. In other words, the light shielding film 26 functions as an electrical path that electrically connects the drive circuit 21 and the first terminal 281, and is configured to block the leakage light emitted from the light emitting elements 30 toward the drive circuit 21.

The light shielding film 26 includes a single layer of metal whose main component is Al, copper (Cu), W or titanium (Ti), for example.

The light absorbing film 27 is placed on the light shielding film 26 to be opposed to the light emitting element 30. The light absorbing film 27 has the same planar shape as the light shielding film 26 when viewed from the direction of arrow Z (hereinafter simply referred to as “plan view”). The light absorbing film 27 absorbs the leaked light emitted from the light emitting elements 30 toward the drive circuit 21, and also serves as an electrical path that electrically connects the drive circuit 21 and the first terminal 281.

The light absorbing film 27 includes a single layer of metal or a metal compound whose main component is titanium nitride (TiN), cobalt (Co), nitrogen-doped titanium oxide (TiON), tantalum nitride (TaN) or amorphous carbon (a-C), for example.

### (2-4) Configuration of First Terminal 281

The first terminal 281 is electrically coupled to the light absorbing film 27 and is placed on the insulator 29. The first terminal 281 is electrically coupled to one end of the light emitting element 30 (specifically, to a second compound semiconductor layer 32). For instance, the first terminal 281 includes Cu, which has a low resistance value.

In the peripheral region 8, the second terminal 282 is placed in the insulator 29. The second terminal 282 is electrically coupled to the other end of the light emitting element 30 (specifically, to a first compound semiconductor layer 31) or to the outside of the light emitting device 1.

In this embodiment, the second terminal 282 is formed in the same conductive layer as the light shielding film 26 and light absorbing film 27, and includes the same conductive material.

### (3) Configuration of Light Emitter Region 3

As illustrated in FIG. 1 and FIG. 2, the light emitter region 3 includes the light emitter 35 placed on the substrate region 2 and on the insulator 29. The light emitter 35 in this embodiment includes the array of a plurality of light emitting elements 30 including compound semiconductor layers, these light emitting elements 30 being arranged along the directions of the light emitting surfaces of the light emitting elements 30 (the directions of arrows X and Y).

The following describes the configuration in detail. In this embodiment, as illustrated in FIG. 2, the light emitting elements 30 each have a hexagonal shape in plan view. These light emitting elements 30 are arranged in the direction of arrow X, and are also arranged in a direction inclined by 30 degrees toward the direction of arrow X relative to the direction of arrow Y (the direction of arrow Y). The light emitting elements 30 include light emitting elements 30(R) that emit red light, light emitting elements 30(B) that emit blue light, and light emitting elements 30(G) that emit green light, where red, blue, and green are the three primary colors of light.

The light emitting elements 30(R), 30(B), and 30(G) are arranged so that their centers exactly coincide with the vertices of equilateral triangles. That is, the light emitting elements 30(R), 30(B), and 30(G) in the first embodiment are in a delta arrangement.

The light emitter 35 also includes an insulator 34 around the plurality of light emitting elements 30 except for the light emitting surface. The insulator 34 mainly includes a SiO film or a SiN film.

### (3-1) Configuration of Light Emitting Elements 30

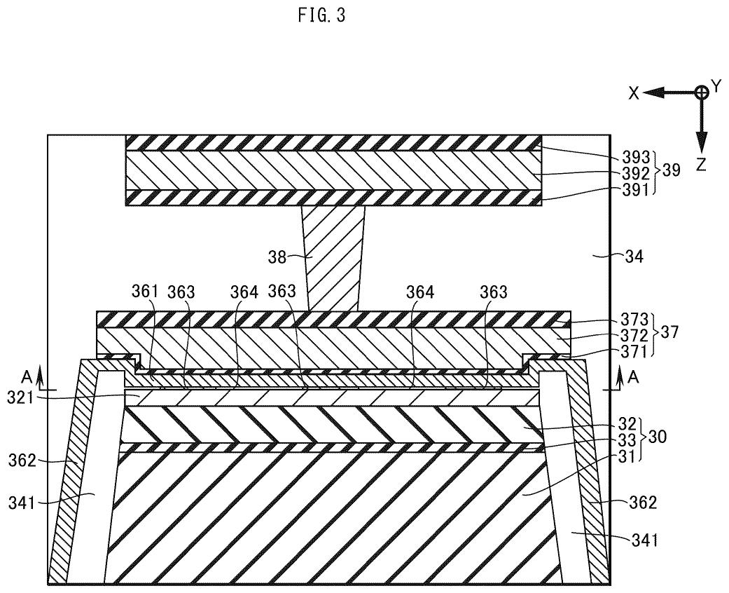

FIG. 3 illustrates an example of an enlarged cross-sectional configuration of a light emitting element 30 that makes up the light emitting device 1. FIG. 4 illustrates an example of the configuration of a first reflective layer 361 and first electrodes 363 of the light emitting element 30. FIG. 4 is a bottom view taken along the A-A line in FIG. 3, viewed from the direction opposite to arrow Z direction.

It should be noted that the bottom view corresponding to FIG. 4 used in the second and subsequent embodiments described later is taken along at a similar position.

As illustrated in FIGS. 1 and 3, each light emitting element 30 is configured as a light emitting diode (LED) including a first compound semiconductor layer 31, a second compound semiconductor layer 32, and an active layer 33. Note that, in FIG. 1 and FIG. 3, the directions of arrow Z for the light emitting elements 30 are opposite.

For instance, each light emitting elements 30 mainly includes a III-V group compound semiconductor. The first compound semiconductor layer 31 is placed closer to the color conversion region 4 and on the light emitting side. For instance, the first compound semiconductor layer 31 includes n-type gallium nitride (n-GaN). Here, “n-type” refers to a “first conductivity type” according to the present technology.

The second compound semiconductor layer 32 is placed closer to the substrate region 2. For instance, the second compound semiconductor layer 32 includes p-type gallium nitride (p-GaN). Here, “p-type” refers to a “second conductivity type,” which is the opposite of the first conductivity type according to the present technology.

The active layer 33 is placed between the first compound semiconductor layer 31 and the second compound semiconductor layer 32. In other words, the active layer 33 is stacked on the first compound semiconductor layer 31, and the second compound semiconductor layer 32 is stacked on the active layer 33 on the opposite side of the first compound semiconductor layer 31. The active layer 33 serves as a light emitting layer that emits light. Although not limited thereto, the light emitting elements 30 in the first embodiment emit blue light.

In each light emitting element 30, at least a portion of the first compound semiconductor layer 31, the active layer 33, and the second compound semiconductor layer 32 are in a mesa shape in cross section. That is, as described above, the light emitting element 30 has a hexagonal shape in plan view, and has a mesa shape viewed in the direction of arrow Y (hereinafter simply referred to as “side view”).

Note that the planar shape of the light emitting element 30 is not limited to a hexagon. The planar shape of the light emitting element 30 may be circular, rectangular, and others.

### (3-2) Configuration of Transparent Electrode 321

In the light emitting element 30, a transparent electrode 321 is placed on the surface (closer to the substrate region 2) of the second compound semiconductor layer 32. The transparent electrode 321 is electrically coupled to substantially the entire surface of the second compound semiconductor layer 32. The transparent electrode 321, which is formed for each light emitting element 30, has the same planar shape as the second compound semiconductor layer 32 in plan view. For instance, the transparent electrode 321 includes indium tin oxide (ITO). With this configuration, the transparent electrode 321 connects to the second compound semiconductor layer 32 by ohmic contact.

### (3-3) Configuration of First Reflective Layer 361

As illustrated in FIGS. 1 through 4, each of the plurality of light emitting elements 30 has a first reflective layer 361, a first electrode 363, an insulator 364, a second reflective layer 362, and a second electrode 37.

First, the first reflective layer 361 will be described in detail. The first reflective layer 361 is placed over the entire second compound semiconductor layer 32 (over its surface closer to the substrate region 2), with the transparent electrode 321 interposed therebetween to be spaced apart from the second compound semiconductor layer 32. In other words, the first reflective layer 361 is placed over the entire surface of the transparent electrode 321 (over its surface closer to the substrate region 2) to be spaced apart from the transparent electrode 321.

The first reflective layer 361 includes a metal material that is electrically conductive and has a high light reflectance of 75% or more for blue light having a wavelength of 400 nm, for example. That is, the first reflective layer 361 is configured to supply the second compound semiconductor layer 32 with the current necessary for the light emission of the light emitting element 30 and to ensure the reflection of the light emitted from the active layer 33.

For instance, the first reflective layer 361 includes Al (preferably pure Al). For example, when Al is 75 nm in thickness, it has a reflectance of 92.5% for blue light. When Al is less than 50 nm in thickness, the reflectance of the layer starts to decrease for blue light. For this reason, the thickness of the first reflective layer 361 may be 50 nm or more, and from the viewpoint of manufacturing, it is 100 nm or less.

Note that, other than Al, the first reflective layer 361 may include one or more materials selected from an Al alloy, Ag, and an Ag alloy.

In the light emitting element 30 in this embodiment, light emitted from the active layer 33 passes through the second compound semiconductor layer 32 to reach the first reflective layer 361, and is reflected by the first reflective layer 361. The reflected light then passes through the second compound semiconductor layer 32, the active layer 33, and the first compound semiconductor layer 31, and then is output. The thickness of the second compound semiconductor layer 32 therefore is set to a thickness at which the light before and after the reflection at the first reflective layer 361 is not interfered with and attenuated, but is conversely amplified to ultimately enhance the light extraction efficiency.

### (3-4) Configuration of First Electrode 363

The first electrode 363 is placed between the second compound semiconductor layer 32 and the first reflective layer 361. In the first embodiment, the first electrode 363 is placed between the transparent electrode 321 and the first reflective layer 361. The first electrode 363 electrically connects a portion of the second compound semiconductor layer 32 or transparent electrode 321 and the first reflective layer 361.

The first electrode 363 is used as a contact metal. In contrast to a direct connection between the first reflective layer 361 and the transparent electrode 321, the connection of the first reflective layer 361 to the transparent electrode 321 via the first electrode 363 leads to a good electrical conduction.

For instance, the first electrode 363 includes Ti or Ti alloy. The first electrode 363 has a thickness of 10 nm or more and 100 nm or less, for example.

As illustrated in FIG. 4, this embodiment has seven first electrodes 363 for one first reflective layer 361 in plan view. Specifically, the first electrodes 363 each have a circular shape in plan view. Of these first electrodes 363, one is placed at the middle of the first reflective layer 361 having a hexagonal shape in plan view, and six are equally spaced at peripheral positions corresponding to the corners of the first reflective layer 361.

The area of these seven electrodes in total as viewed from the thickness direction of the first electrode 363 is smaller than the area of the first reflective layer 361 as viewed from the same direction. Specifically, the total area of the first electrodes 363 is 1% or more and 30% or less of the area of the first reflective layer 361.

Such an area ratio of the first electrodes 363 suppresses the voltage drop due to the first electrodes 363 to be 10 mV or less, for example, which does not affect the driving current of the light emitting element 30. The reflectance of the first electrodes 363 is lower than the reflectance of the first reflective layer 361. That is, the area of the first electrodes 363 covering the first reflective layer 361 is small. This increases the area of the first reflective layer 361 that contributes to reflection, and suppresses a decrease in light extraction efficiency to be 30% or less.

Note that the planar shape of the first electrodes 363 is not limited to a circular shape. The planar shape of the first electrodes 363 may be an ellipse, a triangle, a rectangle, a polygon including a pentagon or more, a slit shape, or others.

### (3-5) Configuration of Insulator 364

As illustrated in FIG. 3, the insulator 364 is placed around the first electrode 363 between the first reflective layer 361 and the transparent electrode 321. In other words, the insulator 364 is placed between the first reflective layer 361 and the transparent electrode 321 except for the region where the first electrode 363 is placed. The insulator 364 is light transmissive and insulating, and serves as a barrier layer that separates the first reflective layer 361 and the transparent electrode 321.

For instance, the insulator 364 includes aluminum oxide (AIO) or SiO. The insulator 364 has a thickness that is effectively the same as the thickness of the first electrode 363. For instance, the insulator 364 is formed by atomic layer deposition (ALD).

### (3-5) Configuration of Second Reflective Layer 362

As illustrated in FIGS. 1 and 3, the second reflective layer 362 is placed along and surrounding the side faces of the mesa shape of the first compound semiconductor layer 31, the active layer 33, and the second compound semiconductor layer 32 in side view. An insulator 341 is formed between the second reflective layer 362 and the first compound semiconductor layer 31, the active layer 33, and the second compound semiconductor layer 32. For instance, the insulator 341 includes SiO or SiN.

The second reflective layer 362 reflects light emitted from the active layer 33 and light reflected from the first reflective layer 361 toward the first compound semiconductor layer 31 to enhance the light extraction efficiency.

In the first embodiment, the second reflective layer 362 is formed in the same layer as the first reflective layer 361 and includes the same material as the first reflective layer 361. The second reflective layer 362 is continuous with the first reflective layer 361 and is integral with the first reflective layer 361.

### (3-6) Configuration of Second Electrode 37

As illustrated in FIGS. 1 and 3, a second electrode 37, a plug wiring 38, and a wiring 39 are sequentially placed on the first reflective layer 361.

First, the second electrode 37 will be described. The second electrode 37 is placed on the first reflective layer 361 on the opposite side of the second compound semiconductor layer 32. As illustrated in FIG. 3, the second electrode 37 is formed over the entire first reflective layer 361 in plan view and side view, and has an area slightly larger than the area of the first reflective layer 361. The second electrode 37 is electrically coupled to the second compound semiconductor layer 32 through the first reflective layer 361, the first electrode 363, and the transparent electrode 321.

In the first embodiment, the second electrode 37 is formed by stacking a barrier metal layer 371, an Al alloy layer 372, and a barrier metal layer 373.

For instance, the barrier metal layer 371 includes titanium nitride (TiN) and has a thickness of 10 nm or more and 100 nm or less.

For instance, the Al alloy layer 372 includes made of AlCu in which Cu is added to Al, or AlSi in which Si is added to Al. The amount of Cu added is 1% or more and 3% or less, for example. The amount of Si added is 1% or more and 5% or less, for example. The Al alloy layer 372 has a thickness of 300 nm or more to 800 nm or less, for example.

Like the barrier metal layer 371, the barrier metal layer 373 includes TiN, for example, and has a thickness of 10 nm or more and 100 nm or less.

### (3-7) Configuration of Plug Wiring 38

The plug wiring 38 is electrically connected at one end to the second electrode 37 and at the other end to the wiring 39. The plug wiring 38 is placed at the middle position of the first reflective layer 361 and passes through the insulator 34.

For instance, the plug wiring 38 includes W.

### (3-8) Configuration of Wiring 39

The wiring 39 is formed by sequentially stacking a barrier metal layer 391, an Al alloy layer 392, and a barrier metal layer 393.

Like the barrier metal layer 391, the barrier metal layer 391 includes TiN, for example. For instance, the barrier metal layer 391 has a thickness of 10 nm or more and 100 nm or less.

For instance, the Al alloy layer 392 includes AlCu or AlSi. The Al alloy layer 392 has a thickness of 500 nm or more to 600 nm or less, for example.

Like the barrier metal layer 371, the barrier metal layer 393 includes TiN, for example, and has a thickness of 10 nm or more and 100 nm or less.

The barrier metal layers 391 and 393 of the wiring 39 may each include a composite film in which Ti, TiN, and Ti are sequentially stacked, instead of TiN. In this case, Ti is formed to have a thickness of 30 nm or less, for example. TiN is formed to have a thickness of 10 nm or more and 100 nm or less, for example.

As illustrated in FIG. 1, the wiring 39 connects to a third terminal 390 of the light emitter region 3. The third terminal 390 is formed on the surface (closer to the substrate region 2) of the insulator 34. Like the above-described first terminal 281, the third terminal 390 includes Cu, for example.

The third terminal 390 joins to the first terminal 281 to be electrically coupled to the first terminal 281.

### (3-9) Configuration of Element Isolation Region 300

As illustrated in FIG. 1, the insulator 34 is filled between adjacent light emitting elements 30, and the second reflective layer 362 is placed between each light emitting element 30 and the insulator 34. These insulator 34 and second reflective layer 362 constitute an element isolation region 300 that optically isolates the adjacent light emitting elements 30.

### (3-10) Configuration of Transparent Electrode 311

As illustrated in FIG. 1, a transparent electrode 311 is placed on the first compound semiconductor layer 31 of each light emitting element 30 on the opposite side of the second compound semiconductor layer 32. The transparent electrode 311 is electrically coupled to the first compound semiconductor layer 31. The transparent electrode 311 includes a similar material to the above-described transparent electrode 321.

The first electrode 311 is electrically coupled to wiring 312, which supplies current to the first compound semiconductor layer 31 through the transparent electrode 311. For instance, the wiring 312 includes W.

### (4) Configuration of Color Conversion Region 4

As illustrated in FIG. 1, the color conversion region 4 includes a color conversion layer 40, a third reflective layer 401, and a partition wall 41.

The color conversion layer 40 is placed above the light emitting surface of the light emitting element 30, that is, over the transparent electrode 311 via an insulator without reference numeral. The color conversion layer 40 is placed to correspond to each light emitting element 30. The color conversion layer 40 converts the light emitted from the light emitting element 30 into a specific color. In this embodiment, the light emitting elements 30 are configured to emit blue light, as described above. Thus, the color conversion layer 40 includes a color conversion layer 40(R) that converts blue light into red light, a color conversion layer 40(G) that converts blue light into green light, and a transparent color conversion layer 40(B, T) that lets blue light pass through as is. For instance, the color conversion layer 40 includes a resin material.

With this configuration, the light emitting device 1 according to the first embodiment operates as a color light emitting device. Practically, the light emitting device 1 operates as a color image display device or a micro light emitting device (micro LED).

The third reflective layer 401 is placed along the periphery of the side face of the color conversion layer 40. The third reflective layer 401 reflects light emitted from the light emitting element 30 and light diffused from the color conversion layer 40 to enhance the light extraction efficiency. For instance, the third reflective layer 401 includes a similar material to the first reflective layer 361.

In the color conversion region 4, the partition wall 41 is formed between the adjacent color conversion layers 40 in the planar direction and between the adjacent third reflective layers 401. The partition walls 41 are configured to optically separate the color conversion layers 40 and to hold the color conversion layers 40. For instance, the partition walls 41 include SiO or SiN.

### (5) Configuration of Filter Region 5

A filter region 5 is placed on the color conversion region 4. The filter region 5 in this embodiment includes a distributed bragg reflector (DBR) 50 and a color filter 51 that are sequentially stacked on the color conversion region 4. The DBR 50 reflects light of a specific color. The color filter 51 absorbs light of a specific color. In this embodiment, the specific emission color is blue light, for example.

### (6) Configuration of Optical System Region 6

An optical system region 6 is placed on the filter region 5. In the optical system region 6, an on-chip lens 60 is placed. The on-chip lens 60 includes a plurality of optical lenses that are each placed for a corresponding light emitting element 30 and are integrally formed. These optical lenses each have a cross-sectional shape that protrudes and curves in the light emission direction. For instance, the on-chip lens 60 includes a resin material or an inorganic material.

### Method of Manufacturing Light Emitting Device 1

Next, the manufacturing method of the light emitting device 1 according to the first embodiment will be briefly described.

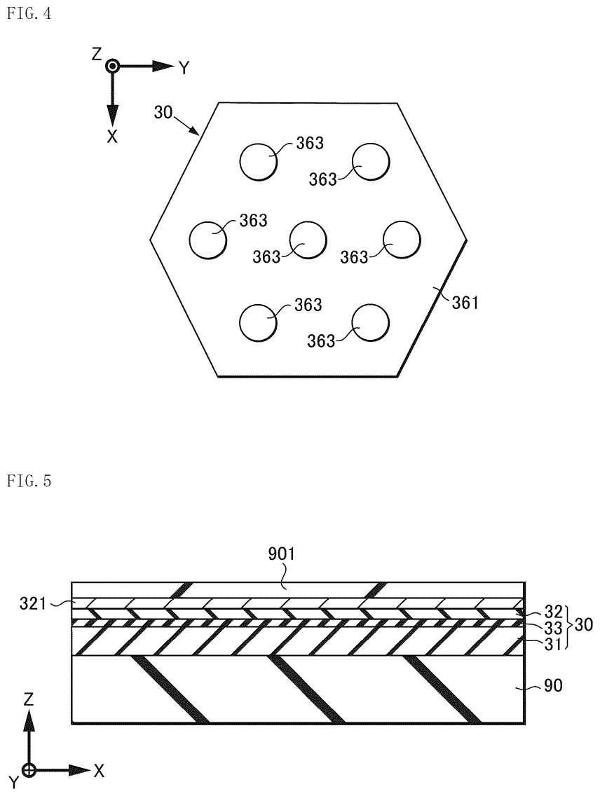

FIGS. 5 through 12 are cross-sectional views of an example of the steps of a method of manufacturing the light emitting device 1 according to the first embodiment.

First, a support substrate 90 is prepared (see FIG. 5). For instance, a sapphire substrate may be used for the support substrate 90. On the support substrate 90, a first compound semiconductor layer (n-GaN) 31, an active layer 33, and a second compound semiconductor layer (p-GaN) 32 are formed sequentially (see FIG. 5). Subsequently, a transparent electrode 321 is formed on the second compound semiconductor layer 32 (see FIG. 5).

As illustrated in FIG. 5, a mask 901 is formed on the transparent electrode 321. The mask 901 is used as an etching mask to form a mesa shape. For instance, the mask 901 includes a single layer film of SiO or SiN or a composite film containing them.

As illustrated in FIG. 6, the transparent electrode 321, second compound semiconductor layer 32, active layer 33, and first compound semiconductor layer 31 are etched using the mask 901. This etching forms a mesa shape of the transparent electrode 321, second compound semiconductor layer 32, active layer 33, and first compound semiconductor layer 31. For instance, the etching is dry etching. After this, the mask 901 is removed.

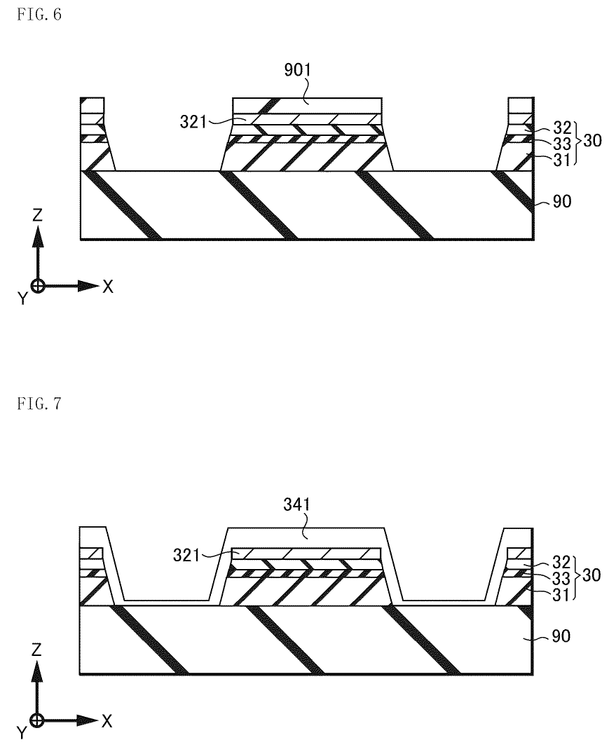

As illustrated in FIG. 7, the insulator 341 is formed along the top and side faces of the mesa shape. For instance, the insulator 341 is formed by the chemical vapor deposition (CVD) method.

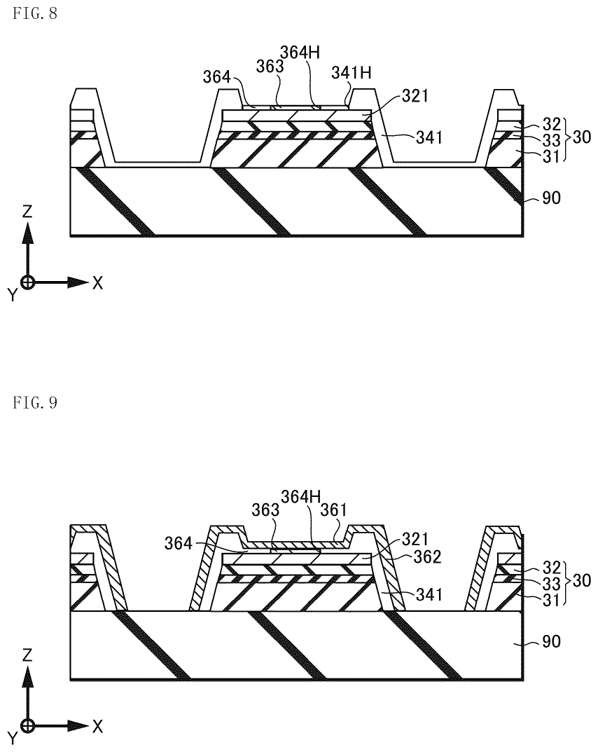

Next, an opening 341H is formed in a portion of the insulator 341 on the top face of the mesa shape to expose the surface of transparent electrode 321 (see FIG. 8). The opening 341H is formed by photolithography and etching techniques.

Subsequently, an insulator 364 is formed on the transparent electrode 321 in the opening 341H (see FIGS. 9 and 3). For instance, the insulator 364 includes AIO or SiO as described above. For instance, the insulator 364 is formed by ALD.

Next, an opening 364H is formed in the insulator 364 at the region where the first electrode 363 is to be formed, exposing the surface of the transparent electrode 321 (see FIG. 9 and FIG. 3). For instance, the opening 364H is formed by photolithography and etching techniques.

As illustrated in FIG. 8, the first electrode 363 is formed in the opening 341H to be electrically coupled to a part of the surface of the transparent electrode 321 through the opening 364H. For instance, the first electrode 363 includes Ti or Ti alloy, as described above. The first electrode 363 is formed by sputtering, for example, followed by patterning using an etching technique to form a predetermined shape.

FIG. 8 through FIG. 12 illustrate the first electrode 363 as a single one to simplify the cross-sectional shape. Actually, however, seven first electrodes 363 are placed in the first embodiment, as illustrated in FIG. 4 above.

As illustrated in FIG. 9, the first reflective layer 361 is formed on the first electrode 363 and on the insulator 364 in the opening 341H. In the same manufacturing step as the first reflective layer 361, a second reflective layer 362 is formed on the insulator 341 along the sidewall of the mesa shape. These first reflective layer 361 and second reflective layer 362 include an Al film formed by a CVD method, for example.

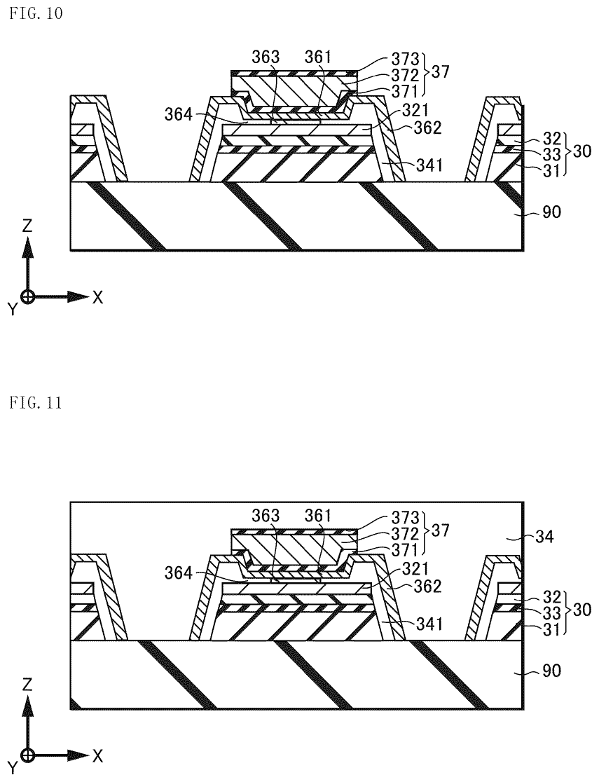

As illustrated in FIG. 10, the second electrode 37 is formed on the first reflective layer 361. The second electrode 37 is formed by sequentially stacking the barrier metal layer 371, the Al alloy layer 372, and the barrier metal layer 373 as described above. These films are formed by sputtering, for example, followed by patterning by an etching technique.

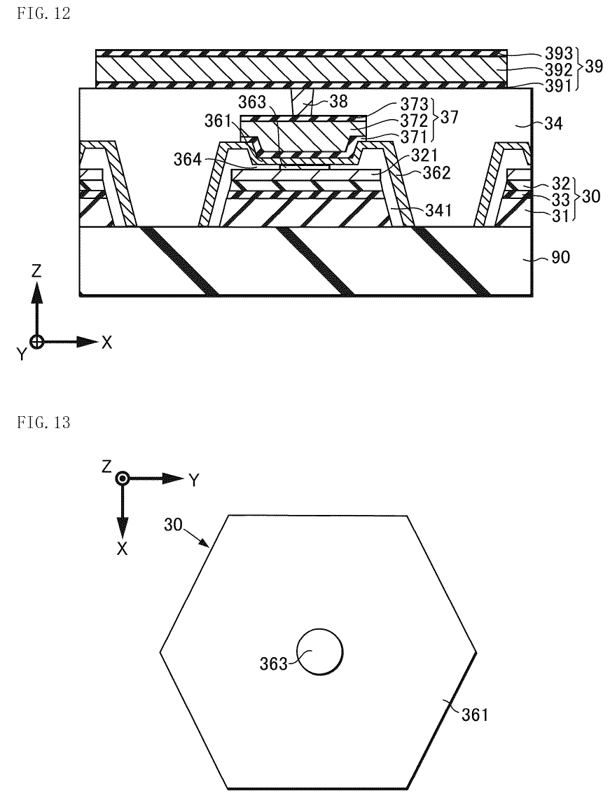

As illustrated in FIG. 11, the insulator 34 is formed to embed the second electrode 37 therein. As illustrated in FIG. 12, the plug wiring 38 is then formed in the insulator 34, and the wiring 39 is formed on the insulator 34.

Once these steps end, the light emitting element 30 is substantially completed. After this, the third terminal 390 is formed on the light emitting element 30, as illustrated in FIG. 1 above. After bonding the substrate region 2, the light emitting element 30 is peeled off from the support substrate 90. After peeling, the color conversion region 4, the filter region 5, and the optical system region 6 are formed sequentially to complete the light emitting device 1 according to the first embodiment.

### Actions and Advantageous Effects

As illustrated in FIGS. 1, 3 and 4, the light emitting device 1 according to the first embodiment includes the first compound semiconductor layer 31, the active layer 33, the second compound semiconductor layer 32, the first reflective layer 361, and the first electrode 363.

The first compound semiconductor layer 31 has the first conductivity type. The active layer 33 is stacked on the first compound semiconductor layer 31. The second compound semiconductor layer 32 is stacked on the active layer 33 on the opposite side of the first compound semiconductor layer 31 and has the second conductivity type opposite to the first conductivity type.

The first reflective layer 361 is placed above the surface of the second compound semiconductor layer 32 on the opposite side of the active layer 33 to be spaced apart therefrom, and reflects light emitted from the active layer 33. The first electrode 363 is placed between the second compound semiconductor layer 32 and the first reflective layer 361, and electrically connects a part of the second compound semiconductor layer 32 and of the first reflective layer 361.

The light emitting device 1 configured in this manner includes the first reflective layer 361 on the surface of the second compound semiconductor layer 32, thus effectively suppressing or preventing the leakage of light emitted from the active layer 33 toward the drive circuit 21. In particular, the first reflective layer 361 is placed over the entire surface of the second compound semiconductor layer 32, thus no light leakage occurs. The first reflective layer 361 is able to efficiently reflect light, thereby enhancing the light extraction efficiency of the light emitting device 1.

As a result of the enhanced light extraction efficiency, this image display device has an enhanced image quality even if their light emitting elements have further miniaturized.

Furthermore, the first reflective layer 361 is coupled to the second compound semiconductor layer 32 via the first electrode 363, and thus the supply of current from the first reflective layer 361 improves, thereby enhancing the light emitting efficiency of the light emitting element 30.

In addition, the first electrode 363 is electrically coupled to a part of the first reflective layer 361 and of the second compound semiconductor layer 32, so that the reflective area of the first reflective layer 361 is sufficiently secured. Thus, the light emitting device 1 is able to have further enhanced light extraction efficiency.

In addition, the first reflective layer 361 enables the blockage of light leakage toward the drive circuit 21, which effectively suppresses or prevents malfunctions of the drive circuit 21 caused by light leakage. This enhances the operational reliability of the light emitting device 1.

As illustrated in FIG. 1 through FIG. 4, the first reflective layer 361 in the light emitting device 1 includes one or more materials selected from Al, Al alloy, Ag and Ag alloy.

For instance, when the thickness of the first reflective layer 361 is 75 nm, the reflectance of blue light having a wavelength of 400 nm is 92.5% for Al, 91.5% for Al alloy (AlCu), 86.2% for Ag, and 84.0% for Ag alloy. This means that the reflectance of the first reflective layer 361 is 75% or higher, which further enhances the light extraction efficiency of the light emitting device 1.

Furthermore, as particularly illustrated in FIG. 3, the light emitting device 1 further includes the transparent electrode 321 between the second compound semiconductor layer 32 and the first electrode 363, and the first electrode 363 is electrically coupled to the second compound semiconductor layer 32 via the transparent electrode 321.

This enables a good electrical connection between the second compound semiconductor layer 32 and the transparent electrode 321, resulting in a good electrical connection between the first reflective layer 361 and the second compound semiconductor layer 32.

Furthermore, as particularly illustrated in FIG. 3, the first electrode 363 of the light emitting device 1 includes Ti or a Ti alloy. This enables a good electrical connection between the first reflective layer 361 and the transparent electrode 321.

As illustrated in FIGS. 3 and 4, the light emitting device 1 is configured so that the area of the first electrodes 363 in total as viewed from the thickness direction is smaller than the area of the first reflective layer 361 as viewed from the same direction. Specifically, the total area of the first electrodes 363 is 1% or more and 30% or less of the area of the first reflective layer 361.

The first electrodes 363 with such an area ratio suppresses the voltage drop due to the first electrodes 363, which does not affect the driving current of the light emitting element 30. In addition, the area of the first electrodes 363 covering the first reflective layer 361 is smaller, thus increasing the reflective area of the first reflective layer 361 and enhancing the light extraction efficiency.

Furthermore, as particularly illustrated in FIG. 3, the light emitting device 1 includes the insulator 364 between the second compound semiconductor layer 32 and the first reflective layer, specifically between the transparent electrode 321 and the first reflective layer 361 except for the region of the first electrode 363. The insulator 364 is light transmissive and insulating.

The insulator 364 therefore is able to effectively suppress or prevent compositional changes in the first reflective layer 361 caused by the transparent electrode 321, thus maintaining the reflectance of the first reflective layer 361 and enhancing the light extraction efficiency.

As particularly illustrated in FIG. 3, the second compound semiconductor layer 32 in the light emitting device 1 has a thickness that amplifies the light extraction efficiency. That is, the second compound semiconductor layer 32 is formed to have an appropriate thickness such that light emitted from the active layer 33 toward the first compound semiconductor layer 31 is not attenuated by the light reflected by the first reflective layer 361 toward the active layer 33.

The light emitting device 1 configured in this way is able to enhance the light extraction efficiency.

In addition, as particularly illustrated in FIG. 3, at least a part of the first compound semiconductor layer 31, the active layer 33 and the second compound semiconductor layer 32 in this light emitting device 1 have a mesa shape. Then, the light emitting device 1 includes the second reflective layer 362 placed along the side face of the mesa shape. The second reflective layer 362 reflects light emitted from the active layer 33 and light reflected from the first reflective layer 361 toward the first compound semiconductor layer 31.

Thus, the light emitting device 1 is able to efficiently extract reflecting light due to the second reflective layer 362, thereby further enhancing the light extraction efficiency.

As particularly illustrated in FIG. 3, the second reflective layer 362 of the light emitting device 1 is formed in the same layer as the first reflective layer 361 and includes the same material as the first reflective layer 361. In addition, the second reflective layer 362 is integrally formed with the first reflective layer 361.

This simplifies the configuration of the light emitting device 1.

In addition, as illustrated in FIG. 9, the method for manufacturing the light emitting device 1 forms the first reflective layer 361 and the second reflective layer 362 in the same step.

This allows one of the originally required steps of forming the first reflective layer 361 and the second reflective layer 362 to be omitted, thus reducing the number of steps in the manufacturing method of the light emitting device 1.

Furthermore, as illustrated in FIGS. 1 and 3, the light emitting device 1 includes the second electrode 37. The second electrode 37 is placed on the first reflective layer 361 on the opposite side of the second compound semiconductor layer 32. The second electrode 37 is formed by sequentially stacking the barrier metal layer 371, the Al alloy layer 372, and the barrier metal layer 373. The second electrode 37 configured in this way is able to enhance electrical reliability of the electrode.

### 2. Second Embodiment

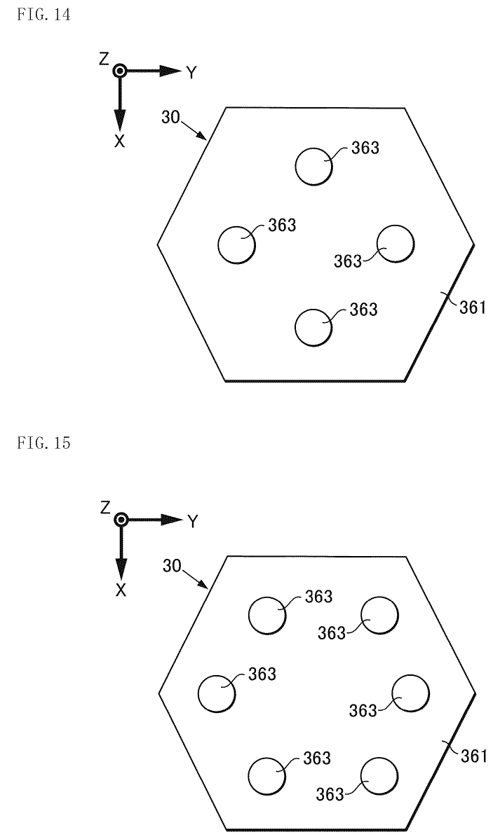

Referring to FIGS. 13 to 15, the following describes a light emitting device 1 according to a second embodiment of the present disclosure. Note that, for the second embodiment and subsequent embodiments, the same or substantially the same components as those of the light emitting device 1 according to the first embodiment are denoted by the same reference numerals, and duplicate explanations will be omitted.

### Configuration of Light Emitting Device 1

FIG. 13 illustrates an example of the configuration of a first reflective layer 361 and a first electrode 363 of a light emitting element 30 in the light emitting device 1 according to the second embodiment.

As illustrated in FIG. 13, the light emitting element 30 of the light emitting device 1 has one first electrode 363 placed at a middle position of a first reflective layer 361 in plan view. The total area ratio of the first electrode 363 to the first reflective layer 361 is the same as that of the light emitting device 1 according to the first embodiment. The planar shape of the first electrode 363 is the same of the planar shape of the first electrodes 363 of the light emitting device 1 according to the first embodiment.

The components other than the above are the same as those of the light emitting device 1 according to the first embodiment, and their descriptions are omitted.

### Actions and Advantageous Effects

With the light emitting device 1 according to the second embodiment, the same actions and advantageous effects are obtainable as those obtained from the light emitting device 1 according to the first embodiment.

### First Modification Example

FIG. 14 illustrates an example of the configuration of a first reflective layer 361 and a first electrode 363 of a light emitting element 30 in the light emitting device 1 according to a first modification example of the second embodiment.

As illustrated in FIG. 14, the light emitting device 1 according to the first modification example includes four first electrodes 363 in total that are placed two in the arrow X direction and two in the arrow Y direction in the first reflective layer 361.

The components other than the above are the same as those of the light emitting device 1 according to the first embodiment, and their descriptions are omitted.

### Actions and Advantageous Effects

With the light emitting device 1 according to the first modification example, the same actions and advantageous effects are obtainable as those obtained from the light emitting device 1 according to the first embodiment.

### Second Modification Example

FIG. 15 illustrates an example of the configuration of a first reflective layer 361 and first electrodes 363 of a light emitting element 30 in the light emitting device 1 according to a second modification example of the second embodiment.

As illustrated in FIG. 15, the light emitting device 1 according to the second modification example includes six first electrodes 363, each of which are equally spaced at peripheral positions corresponding to the corners of the first reflective layer 361 having a hexagonal shape in plan view.

The components other than the above are the same as those of the light emitting device 1 according to the first embodiment, and their descriptions are omitted.

### Actions and Advantageous Effects

With the light emitting device 1 according to the second modification example, the same actions and advantageous effects are obtainable as those obtained from the light emitting device 1 according to the first embodiment.

### 3. Third Embodiment

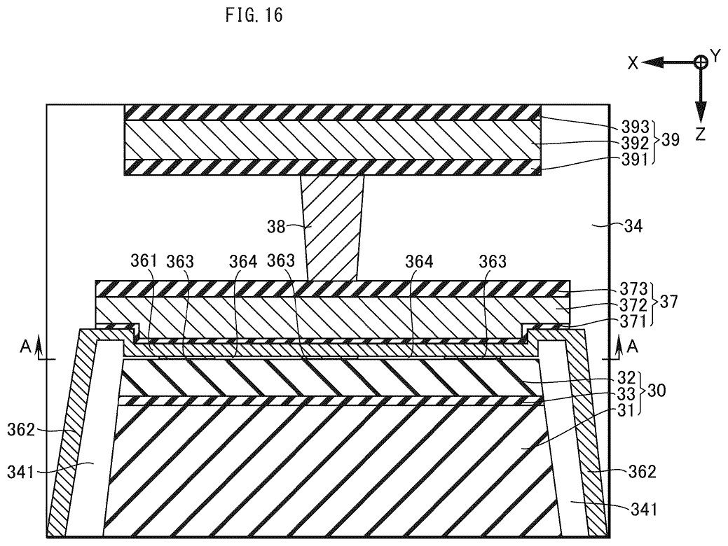

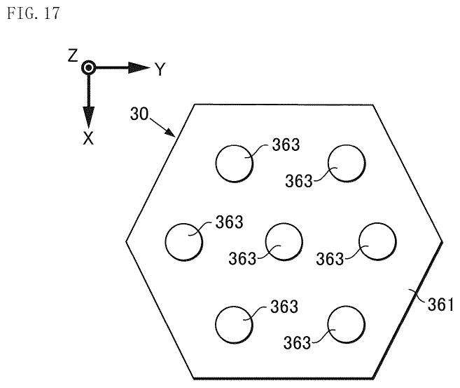

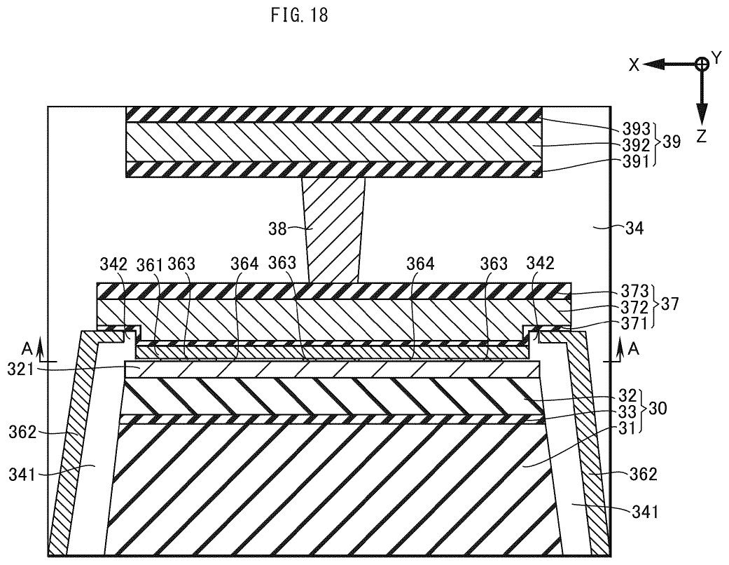

Referring to FIGS. 16 and 17, the following describes a light emitting device 1 according to a third embodiment of the present disclosure.

FIG. 16 illustrates an example of an enlarged cross-sectional configuration of a light emitting element 30 that makes up the light emitting device 1 according to the third embodiment. FIG. 17 illustrates an example of the configuration of a first reflective layer 361 and first electrodes 363 of the light emitting element 30.

### Configuration of Light Emitting Device 1

As illustrated in FIGS. 16 and 17, the light emitting device 1 of the third embodiment does not include a transparent electrode 321 (see FIG. 3) between the second compound semiconductor layer 32 of the light emitting element 30 and the first reflective layer 361. The first reflective layer 361 is directly coupled to the second compound semiconductor layer 32 with a first electrode 363 interposed therebetween.

The transparent electrode 321 is not placed, and thus the first electrodes 363 include Ni, Pd or Cr, for example. These materials are able to be electrically coupled to the second compound semiconductor layer 32 with low resistance. In other words, the first electrodes 363 achieve a good electrical conduction with the second compound semiconductor layer 32.

As illustrated in FIG. 17, the first electrodes 363 have the same arrangement and number of electrodes as the first electrodes 363 illustrated in FIG. 4 of the light emitting device 1 according to the first embodiment. Note that the first electrodes 363 may have the same arrangement and number of electrodes as the first electrode(s) 363 illustrated in FIG. 13, FIG. 14, and FIG. 15 that are the light emitting devices 1 of the second embodiment.

The components other than the above are the same as those of the light emitting device 1 according to the first embodiment, and their descriptions are omitted.

### Actions and Advantageous Effects

With the light emitting device 1 according to the third embodiment, the same actions and advantageous effects are obtainable as those obtained from the light emitting device 1 according to the first embodiment.

### 4. Fourth Embodiment

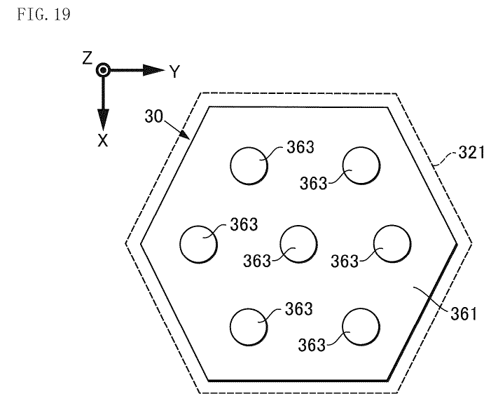

Referring to FIGS. 18 and 19, the following describes a light emitting device 1 according to a fourth embodiment of the present disclosure.

FIG. 18 illustrates an example of an enlarged cross-sectional configuration of a light emitting element 30 that makes up the light emitting device 1 according to the fourth embodiment. FIG. 19 illustrates an example of the configuration of a first reflective layer 361 and first electrodes 363 of the light emitting element 30.

### Configuration of Light Emitting Device 1

As illustrated in FIGS. 18 and 19, the second reflective layer 362 in the light emitting device 1 according to the fourth embodiment is electrically isolated from the first reflective layer 361. Specifically, an insulator 342 is formed between the second reflective layer 362 and the first reflective layer 361. The second reflective layer 362 is electrically floating.

Like the second reflective layer 362 of the light emitting device 1 according to the first embodiment as described above, the second reflective layer 362 is formed in the same layer as the first reflective layer 361 and includes the same material as the first reflective layer 361. The second reflective layer 362 may be formed in a layer different from the first reflective layer 361 and include a material different from the material of the first reflective layer 361.

The components other than the above are the same as those of the light emitting device 1 according to the first embodiment, and their descriptions are omitted.

### Actions and Advantageous Effects

With the light emitting device 1 according to the fourth embodiment, the same actions and advantageous effects are obtainable as those obtained from the light emitting device 1 according to the first embodiment.

As illustrated in FIG. 18, the second reflective layer 362 in the light emitting device 1 is electrically isolated from the first reflective layer 361. With this configuration, no parasitic capacitance is added to the current path from the first reflective layer 361 to the second compound semiconductor layer 32, with the second compound semiconductor layer 32, the active layer 33, and the first compound semiconductor layer 31 as one electrode, the insulator 341 as a dielectric, and the second reflective layer 362 as the other electrode. This increases the drive operation speed of the light emitting elements 30.

### 5. Fifth Embodiment

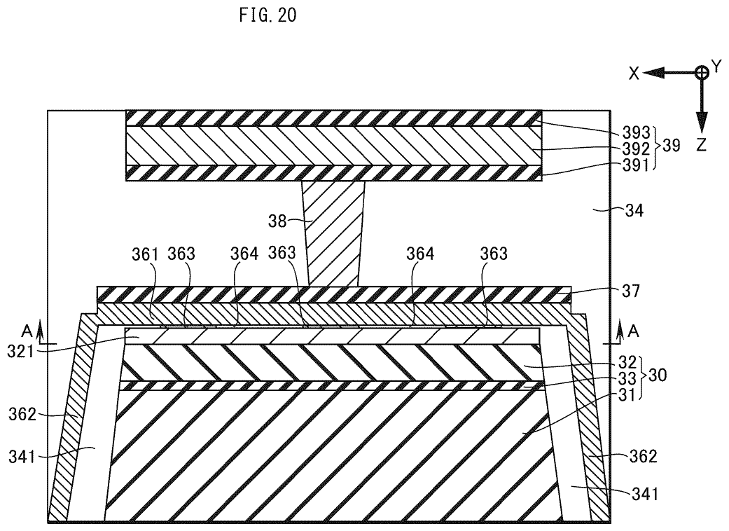

Referring to FIG. 20, the following describes a light emitting device 1 according to a fifth embodiment of the present disclosure.

FIG. 20 illustrates an example of an enlarged cross-sectional configuration of a light emitting element 30 that makes up the light emitting device 1 according to the fifth embodiment.

### Configuration of Light Emitting Device 1

As illustrated in FIG. 20, like the light emitting device 1 according to the first embodiment, a second electrode 37 is placed on a first reflective layer 361 in the light emitting device 1 according to the fifth embodiment. Unlike the second electrode 37 of the light emitting device 1 according to the first embodiment, the second electrode 37 includes a single layer of a barrier metal layer. For instance, the barrier metal layer includes TiN.

The components other than the above are the same as those of the light emitting device 1 according to the first embodiment, and their descriptions are omitted.

Note that the first reflective layer 361 in the fifth embodiment may be made of an Al alloy, although it may lead to a slight reduction in reflectivity. Practically, AlCu may be used as an Al alloy.

### Actions and Advantageous Effects

With the light emitting device 1 according to the fifth embodiment, the same actions and advantageous effects are obtainable as those obtained from the light emitting device 1 according to the first embodiment.

Furthermore, the second electrode 37 in the light emitting device 1 includes a single barrier metal layer as illustrated in FIG. 20. This simplifies the configuration of the device.

### 6. Examples of Applications to Moving Objects

The technique according to the present disclosure (the present technology) is applicable to a variety of products. For example, the technique of the present disclosure may be embodied in the form of an apparatus mounted on any type of moving object, such as an automobile, an electric vehicle, a hybrid electric vehicle, a motorcycle, a bicycle, personal mobility, an airplane, a drone, a ship, or a robot.

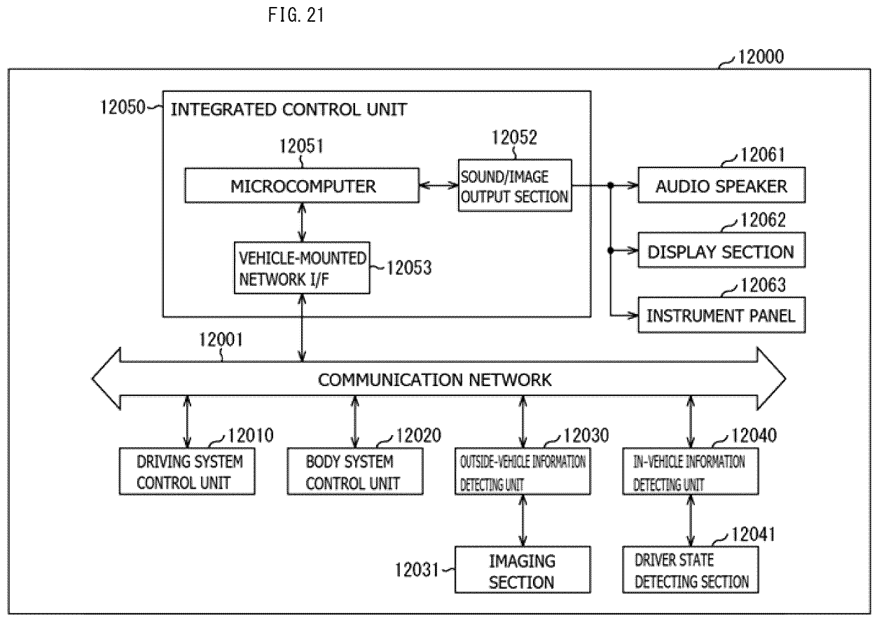

FIG. 21 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

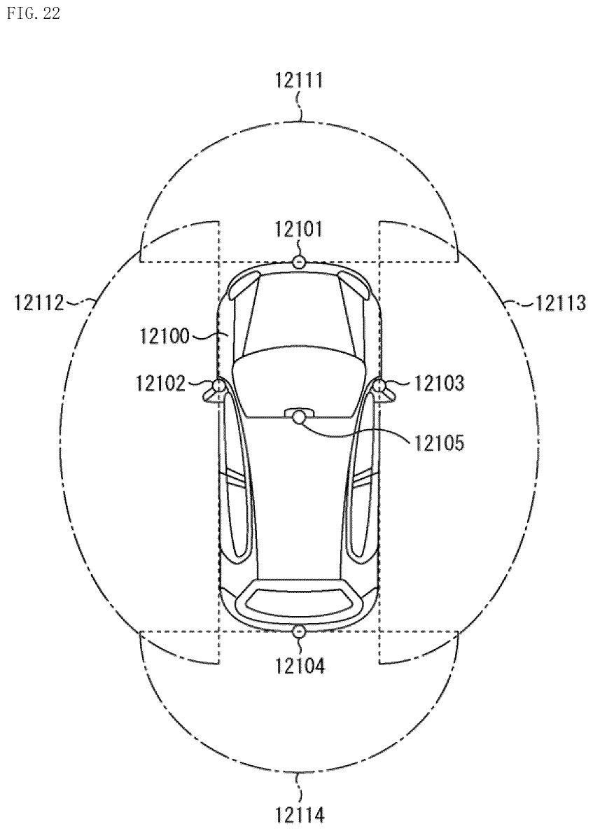

FIG. 22 is a diagram depicting an example of the installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

That is a description on an example of a vehicle control system to which the technique according to the present disclosure is applicable. The technique according to the present disclosure is appliable to the imaging unit 12031 of the above described configuration. Applying the technique according to the present disclosure to the imaging unit 12031 is able to achieve the imaging unit 12031 with a simpler configuration.

### 7. Other Embodiments

The present technology is not limited to the embodiments described above, and is modifiable in various ways without departing from the gist thereof. For instance, two or more of the above-described embodiments may be combined.

The light emitting device according to the first embodiment of the present disclosure includes the first reflective layer placed above the second compound semiconductor layer, thus effectively suppressing or preventing the leakage of light emitted from the active layer. Thus, the first reflective layer is able to efficiently reflect light, thereby enhancing the light extraction efficiency of the light emitting device.

In addition, the first electrode in the light emitting device is electrically coupled to a part of the first reflective layer and of the second compound semiconductor layer, so that the reflective area of the first reflective layer is sufficiently secured, and the light extraction efficiency further enhances.

The light emitting device according to the second embodiment of the present disclosure further includes an insulator in the light emitting device according to the first embodiment. The insulator is placed between the second compound semiconductor layer and the first reflective layer, specifically between the transparent electrode and the first reflective, and is light transmissive and insulating.

The insulator therefore is able to effectively suppress or prevent compositional changes in the first reflective layer caused by the transparent electrode, thus maintaining the reflectance of the first reflective layer and enhancing the light extraction efficiency.

The light emitting device according to the third embodiment of the present disclosure includes the second reflective layer along the mesa-shaped side face of at least a portion of the first compound semiconductor layer, the active layer, and the second compound semiconductor layer in the light emitting device according to the first embodiment or the second embodiment. The second reflective layer reflects light emitted from the active layer and light reflected from the first reflective layer toward the first compound semiconductor layer.

Thus, the light emitting device is able to efficiently extract light due to the second reflective layer, thereby further enhancing the light extraction efficiency.

The light emitting device according to the fourth embodiment of the present disclosure further includes the second electrode on the first reflective layer on the opposite side of the second compound semiconductor layer in the light emitting device according to any of the first through third embodiments. The second electrode is formed by sequentially stacking the barrier metal layer, the Al alloy layer, and the barrier metal layer.

This improves electrical reliability of the second electrode in light emitting device.

### Configuration of the Present Technology

The present technology has the following configuration. The following configuration of the present technology is able to enhance the light extraction efficiency of the light emitting device.
(1)

A light emitting device including:
a first compound semiconductor layer having a first conductivity type;
an active layer stacked on the first compound semiconductor layer;
a second compound semiconductor layer on the active layer stacked on an opposite side of the first compound semiconductor layer, the second compound semiconductor layer having a second conductivity type opposite to the first conductivity type;
a first reflective layer disposed away from a surface of the second compound semiconductor layer on an opposite side of the active layer, the first reflective layer reflecting light emitted from the active layer; and
a first electrode disposed between the second compound semiconductor layer and the first reflective layer, and electrically connecting a part of the second compound semiconductor layer and of the first reflective layer.
(2)

The light emitting device according to (1), in which the first reflective layer includes one or more materials selected from Al, Al alloy, Ag and Ag alloy.
(3)

The light emitting device according to (1) or (2), further including a transparent electrode between the second compound semiconductor layer and the first electrode, in which
the first electrode is electrically coupled to the second compound semiconductor layer with the transparent electrode interposed therebetween.
(4)

The light emitting device according to (3), in which the first electrode includes Ti or a Ti alloy.
(5)

The light emitting device according to (2), in which the first electrode includes Ni, Pd or Cr.
(6)

The light emitting device according to any one of (1) to (5), in which the first electrode includes a plurality of the first electrodes.
(7)

The light emitting device according to (6), in which the first electrodes have an area viewed from a thickness direction of the first electrode that is smaller than an area of the first reflective layer viewed from a same direction.
(8)

The light emitting device according to (6) or (7), in which a total area of the first electrodes is 1% or more and 30% or less of an area of the first reflective layer.
(9)

The light emitting device according to any one of (1) to (8), in which the first reflective layer has a reflectance of 75% or more for blue light.
(10)

The light emitting device according to any one of (1) to (9), further including an insulator between the second compound semiconductor layer and the first reflective layer, the insulator being light transmissive and insulating.
(11)

The light emitting device according to (10), in which the insulator includes AIO, SiO, or SiN.
(12)

The light emitting device according to any one of (1) to (11), in which the second compound semiconductor layer has a thickness that amplifies a light extraction efficiency.
(13)

The light emitting device according to any one of (1) to (11), in which at least a portion of the first compound semiconductor layer, the active layer, and the second compound semiconductor layer have a mesa shape, and
the light emitting device further includes a second reflective layer disposed along a side face of the mesa shape, the second reflective layer reflecting light emitted from the active layer and light reflected from the first reflective layer toward the first compound semiconductor layer.
(14)

The light emitting device according to (13), in which the second reflective layer is in a same layer as the first reflective layer and includes a same material as the first reflective layer.
(15)

The light emitting device according to (13) or (14), in which the second reflective layer is integral with the first reflective layer.
(16)

The light emitting device according to (13), in which the second reflective layer is electrically isolated from the first reflective layer.
(17)

The light emitting device according to (16), in which the second reflective layer includes a material different from a material of the first reflective layer.
(18)

The light emitting device according to any one of (1) to (17), further including a second electrode on the first reflective layer on an opposite side of the second compound semiconductor layer, the second electrode including a lamination of a barrier metal layer, an Al alloy layer, and a barrier metal layer that are sequentially stacked.
(19)

The light emitting device according to (18), further including wiring that is electrically coupled to the second electrode with a plug wiring interposed therebetween.
(20)

The light emitting device according to any one of (1) to (19), in which the first compound semiconductor layer, the active layer, and the second compound semiconductor layer constitute a light emitting element, and
the light emitting element includes an array of a plurality of the light emitting elements that constitutes a micro light emitting device.

The present application claims the benefit of Japanese Priority Patent Application JP2022-131103 filed with the Japan Patent Office on Aug. 19, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A light emitting device, comprising:
a first compound semiconductor layer having a first conductivity type;
an active layer stacked on the first compound semiconductor layer;
a second compound semiconductor layer on the active layer stacked on an opposite side of the first compound semiconductor layer, the second compound semiconductor layer having a second conductivity type opposite to the first conductivity type;
a first reflective layer disposed away from a surface of the second compound semiconductor layer on an opposite side of the active layer, the first reflective layer reflecting light emitted from the active layer; and
a first electrode disposed between the second compound semiconductor layer and the first reflective layer, and electrically connecting a part of the second compound semiconductor layer and of the first reflective layer.

2. The light emitting device according to claim 1, wherein the first reflective layer includes one or more materials selected from Al, Al alloy, Ag and Ag alloy.

3. The light emitting device according to claim 2, further comprising a transparent electrode between the second compound semiconductor layer and the first electrode, wherein
the first electrode is electrically coupled to the second compound semiconductor layer with the transparent electrode interposed therebetween.

4. The light emitting device according to claim 3, wherein the first electrode includes Ti or a Ti alloy.

5. The light emitting device according to claim 2, wherein the first electrode includes Ni, Pd or Cr.

6. The light emitting device according to claim 1, wherein the first electrode includes a plurality of the first electrodes.

7. The light emitting device according to claim 6, wherein the first electrodes have an area viewed from a thickness direction of the first electrode that is smaller than an area of the first reflective layer viewed from a same direction.

8. The light emitting device according to claim 7, wherein a total area of the first electrodes is 1% or more and 30% or less of an area of the first reflective layer.

9. The light emitting device according to claim 1, wherein the first reflective layer has a reflectance of 75% or more for blue light.

10. The light emitting device according to claim 1, further comprising an insulator between the second compound semiconductor layer and the first reflective layer, the insulator being light transmissive and insulating.

11. The light emitting device according to claim 10, wherein the insulator includes AIO, SiO, or SiN.

12. The light emitting device according to claim 1, wherein the second compound semiconductor layer has a thickness that amplifies a light extraction efficiency.

13. The light emitting device according to claim 1, wherein at least a portion of the first compound semiconductor layer, the active layer, and the second compound semiconductor layer have a mesa shape, and
the light emitting device further includes a second reflective layer disposed along a side face of the mesa shape, the second reflective layer reflecting light emitted from the active layer and light reflected from the first reflective layer toward the first compound semiconductor layer.

14. The light emitting device according to claim 13, wherein the second reflective layer is in a same layer as the first reflective layer and includes a same material as the first reflective layer.

15. The light emitting device according to claim 13, wherein the second reflective layer is integral with the first reflective layer.

16. The light emitting device according to claim 13, wherein the second reflective layer is electrically isolated from the first reflective layer.

17. The light emitting device according to claim 16, wherein the second reflective layer includes a material different from a material of the first reflective layer.

18. The light emitting device according to claim 1, further comprising a second electrode on the first reflective layer on an opposite side of the second compound semiconductor layer, the second electrode including a lamination of a barrier metal layer, an Al alloy layer, and a barrier metal layer that are sequentially stacked.

19. The light emitting device according to claim 18, further comprising wiring that is electrically coupled to the second electrode with a plug wiring interposed therebetween.

20. The light emitting device according to claim 1, wherein the first compound semiconductor layer, the active layer, and the second compound semiconductor layer constitute a light emitting element, and
the light emitting element includes an array of a plurality of the light emitting elements that constitutes a micro light emitting device.
